(19) United States
(12) Patent Application Publication
(10) Pub. No.: US 2024/0036481 A1
(43) Pub. Date: Feb. 1, 2024

(54) MASK POD BOX AND MASK TRANSFER DEVICE

(71) Applicant: CHANGXIN MEMORY TECHNOLOGIES, INC., Hefei City, Anhui (CN)

(72) Inventor: Chuang SHAN, Hefei City, Anhui (CN)

(73) Assignee: CHANGXIN MEMORY TECHNOLOGIES, INC., Hefei City, Anhui (CN)

(21) Appl. No.: 17/606,746

(22) PCT Filed: Jun. 16, 2021
(86) PCT No.: PCT/CN2021/100461

§ 371 Date: Dec. 8, 2022

(30) Foreign Application Priority Data
Jun. 1, 2021 (CN) 202110611268.9

(51) Int. Cl. G03F 7/00; G03F 1/66

(52) U.S. Cl. CPC G03F 7/70741; G03F 1/66

(57) ABSTRACT

A mask pod box includes a box body and a box cover, an accommodating space is provided in the box body, an opening connecting the accommodating space and the outside is arranged on a side portion of the box body, a mask is placed into the accommodating space through the opening, the box cover is detachably installed at the side portion of the box body to close the opening.

### CROSS-REFERENCE TO RELATED APPLICATIONS

The present disclosure claims the priority to Chinese Patent Application 202110611268.9, titled “MASK POD BOX AND MASK TRANSFER DEVICE”, filed with China National Intellectual Property Administration on Jun. 1, 2021, which is incorporated herein by reference in its entirety.

### TECHNICAL FIELD

The present disclosure relates to, but is not limited to, a mask pod box and a mask transfer device.

### BACKGROUND

Photolithography is one of the key steps in the semiconductor manufacturing process, which is designed to copy the pattern on the mask to the wafer by means of photoetching. The cleanliness of the mask is an important factor affecting the quality of photolithography.

During the transfer process, the mask is usually held in the mask pod box to prevent the mask from being contaminated by external dust, particles, etc. When placed on the carrying platform, the mask pod box is split up and down to expose the mask. Then the mask is clamped and fed into a device, thereby completing the transfer process of the mask.

When the mask is clamped and fed into the device, if there are contaminants such as dust or particles on the carrying platform, the dust or particles will be brought into the device due to airflow disturbance, thereby contaminating the inside of the device and the mask. This may cause a device failure and reduce production efficiency, and even cause a wafer defect and affect the product yield.

### SUMMARY

An overview of the subject matter detailed in the present disclosure is provided below, which is not intended to limit the protection scope of the claims.

The present disclosure provides a mask pod box and a mask transfer device.

A first aspect of the embodiments of the present disclosure provides a mask pod box. The mask pod box includes:
a box body, where an accommodating space is provided in the box body; an opening connecting the accommodating space and the outside is arranged on a side portion of the box body; a mask is placed in the accommodating space through the opening; and
a box cover, where the box cover is detachably connected and installed at the side portion of the box body to close the opening.

According to some embodiments of the present disclosure, the box body may include a mounting portion and a box main body; the mounting portion may be fixed to the box main body; the box cover may be detachably connected with the box main body by the mounting portion.

According to some embodiments of the present disclosure, the mounting portion may include two protruding structures; the two protruding structures may be separately arranged on two sides of the opening; the box cover may be clamped between the two protruding structures.

According to some embodiments of the present disclosure, the protruding structure may be provided with an insertion groove; the insertion groove penetrates the protruding structure along an extending direction of the protruding structure; an edge of the box cover may be placed in the insertion groove.

According to some embodiments of the present disclosure, the box cover may be an integral structure; the box cover may include a cover main body and an insertion body that may be matched with the insertion groove;
the cover main body may be able to slide along the insertion groove by the insertion body to open or close the opening.

According to some embodiments of the present disclosure, the mounting portion may be a frame structure; the box cover may be embedded in the frame structure to close the opening.

According to some embodiments of the present disclosure, the mask pod box may further include a sealing structure arranged on the side portion of the box body and located between the box body and the box cover; the sealing structure may be arranged along a circumferential direction of the opening.

According to some embodiments of the present disclosure, the sealing structure may be made of an elastic rubber material.

According to some embodiments of the present disclosure, an orthographic projection area of the opening on the side portion of the box body may be larger than the orthographic projection area of the mask on the side portion of the box body.

According to some embodiments of the present disclosure, the mask pod box may further include a plurality of supporting bodies; the plurality of supporting bodies may be arranged on an inner bottom wall of the accommodating space; the mask may be placed on the plurality of supporting bodies.

According to some embodiments of the present disclosure, a convex platform may be further arranged on an outer wall of one side of the box cover away from the opening.

According to some embodiments of the present disclosure, a grip portion may be arranged on an upper surface of the box body along a thickness direction of the mask pod box.

A second aspect of the embodiments of the present disclosure provides a mask transfer device. The mask transfer device includes a driving device and the mask pod box as described above, where the driving device drives the box cover to move along the thickness direction of the mask pod box to open or close the opening.

According to some embodiments of the present disclosure, the driving device may include a moving unit; the moving unit may be able to drive the box cover to move relative to the box body.

According to some embodiments of the present disclosure, the moving unit may include a sliding groove and a moving slider slidably connected with the sliding groove;
the moving unit may further include a first driving portion; the first driving portion may be able to drive the moving slider to slide in the sliding groove.

According to some embodiments of the present disclosure, the driving device may further include an adsorption unit; the adsorption unit may be connected with the box cover and the moving slider, respectively.

According to some embodiments of the present disclosure, one end of the adsorption unit may be connected with a negative pressure generating device, and the other end of the adsorption unit may be connected with the box cover;
the negative pressure generating device may be configured to generate a negative pressure on a surface where the adsorption unit and the box cover may be connected, such that the box cover may be adsorbed to the other end of the adsorption unit.

According to some embodiments of the present disclosure, the adsorption unit may include a connecting rod, and an air flow passage may be provided in the connecting rod.

According to some embodiments of the present disclosure, the mask transfer device may further include a second driving portion and a driving arm; the second driving portion may be able to drive the driving arm to move between an initial position and the accommodating space, so as to transfer the mask.

According to some embodiments of the present disclosure, the mask transfer device may further include a device body; the device body may be provided therein with an operating space, and the device body may be provided with an inlet connecting the outside and the operating space.

According to the mask pod box and the mask transfer device of the embodiments of the present disclosure, the opening is arranged on the side portion of the box body. When the box cover is dismounted, contaminants such as particles outside the box body will not fall from above to the mask or the accommodating space, but are effectively intercepted, thereby avoiding contamination. Meanwhile, the opening is located on the side portion of the box body, corresponding to the inlet of the mask transfer device, such that the mask can directly enter the device from the side opening. This design avoids airflow disturbance and prevents particles on the carrying platform from being brought into the device.

Other aspects of the present disclosure are understandable upon reading and understanding the drawings and detailed description.

### BRIEF DESCRIPTION OF THE DRAWINGS

The drawings incorporated into the specification and constituting a part of the specification illustrate the embodiments of the present disclosure, and are used together with the description to explain the principles of the present disclosure. In these drawings, similar reference signs are used to represent similar elements. The drawings in the following description are a part rather than all of the embodiments of the present disclosure. Persons of ordinary skill in the art may obtain other drawings based on these drawings without creative efforts.

FIG. 1 is an exploded view of a mask pod box according to an embodiment of the present disclosure.

FIG. 2 is a cross-sectional view of the mask pod box according to an embodiment of the present disclosure.

FIG. 3 is a schematic structural diagram of a box body according to an embodiment of the present disclosure.

FIG. 4 is an exploded view of a mounting portion and a box cover according to an embodiment of the present disclosure.

FIG. 5 is an exploded view of a mounting portion and a box cover according to an embodiment of the present disclosure.

FIG. 6 is an exploded view of a mounting portion and a box cover according to an embodiment of the present disclosure.

FIG. 7 is an exploded view of a mounting portion and a box cover according to an embodiment of the present disclosure.

FIG. 8 is a schematic structural diagram of a box cover according to an embodiment of the present disclosure.

FIG. 9 is a schematic structural diagram of a mask transfer device according to an embodiment of the present disclosure.

FIG. 10 is a schematic structural diagram of a mask transfer device according to an embodiment of the present disclosure.

### REFERENCE NUMERALS

1. mask pod box; 11. box body; 111. accommodating space; 112. side portion; 1121. opening; 113. mounting portion; 1131. protruding structure; 1132. insertion groove; 1133. limiting block; 1134. hollow region; 114. box main body;
12. box cover; 13. mask; 121. cover main body; 122. insertion body; 123. convex platform;
14. sealing structure; 15. supporting body; 16. grip portion;
2. driving device;
21. moving unit; 211. sliding groove; 212. moving slider; 213. first driving portion; 22. adsorption unit; 221. connecting rod; 222. air flow passage;
3. carrying platform;
4. device body; 41. operating space; 411. inlet;
5. second driving portion;
6. driving arm.

### DETAILED DESCRIPTION

In order to make the objectives, technical solutions and advantages of the embodiments of the present disclosure clearer, the technical solutions in embodiments of the present disclosure are described below clearly and completely with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts should fall within the protection scope of the present disclosure. It should be noted that the embodiments in the present disclosure and features in the embodiments may be combined with each other in a non-conflicting manner.

The present disclosure proposes a mask pod box and a mask transfer device, which are described below with reference to the accompanying drawings and specific implementations.

The present disclosure proposes a mask pod box. The mask pod box includes a box body and a box cover. An accommodating space is provided in the box body, and the accommodating space is used to hold a mask. An opening connecting the accommodating space and the outside is arranged on a side portion of the box body. The box cover is detachably connected with the side portion of the box body. The box cover is arranged on the box body to close the opening. The opening is arranged on the side portion of the box body. When the box cover is dismounted, contaminants such as particles outside the box body will not fall from above to the mask or the accommodating space, but are effectively intercepted, thereby avoiding contamination. Meanwhile, the opening is located on the side portion of the box body, corresponding to an inlet of a mask transfer device, such that the mask can directly enter the device from the side opening. This design avoids airflow disturbance and prevents particles on a carrying platform from being brought into the device.

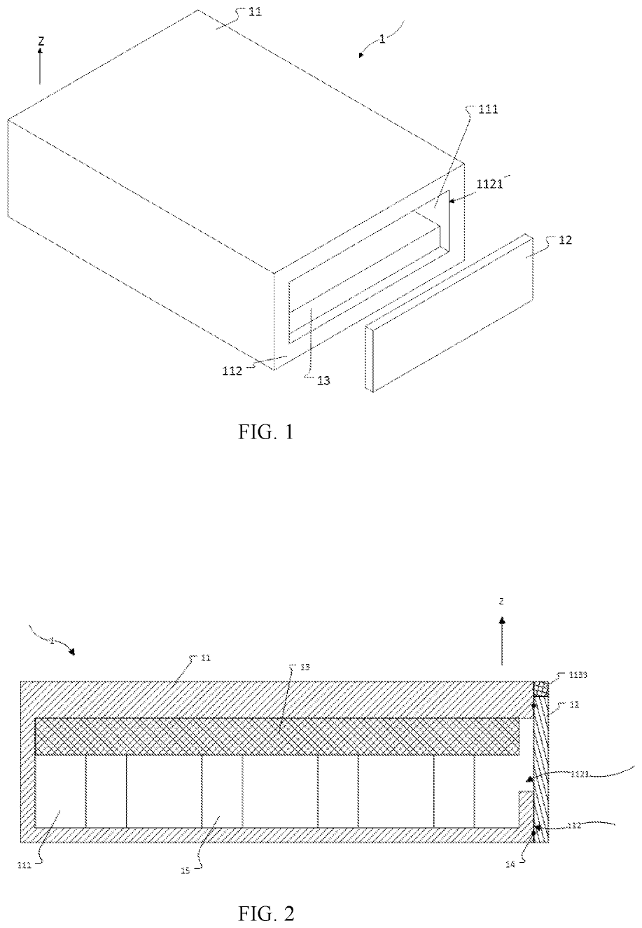

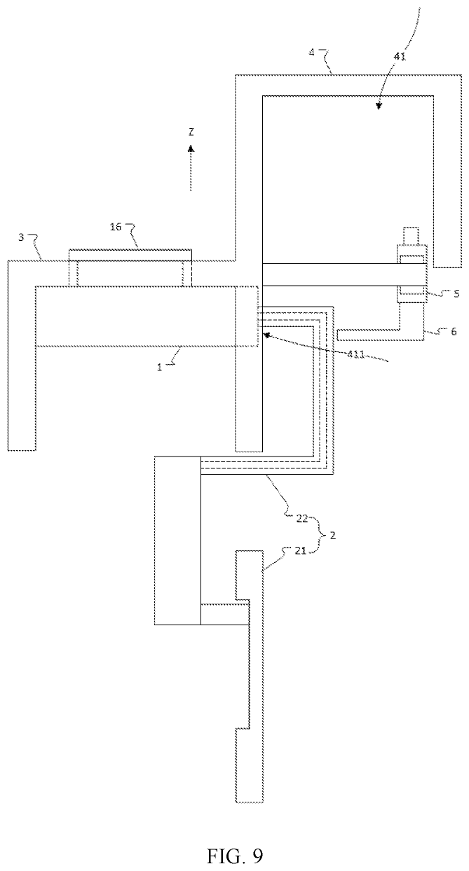

In an embodiment of the present disclosure, as shown in FIGS. 1 and 9, a mask pod box 1 includes a box body 11 and a box cover 12. The box body 11 and the box cover 12 are detachably connected.

The box body 11 may be formed by in-mold molding. An accommodating space 111 is provided in the box body 11, and the accommodating space 111 is used to hold a mask 13. The mask 13 may be made of a quartz material. In the semiconductor manufacturing process, the mask 13 is used as a master to copy a pattern thereon to a wafer by means of light passing through the mask, which is so called photolithography. The pattern on the mask 13 may be a circuit layout diagram, etc.

The box body 11 includes a side portion 112. The side portion 112 of the box body 11 is provided with an opening 1121 connecting the accommodating space 111 and the outside. The opening 1121 is adapted to the mask 13, and the mask 13 can be placed in the accommodating space 111 through the opening 1121. The opening 1121 is arranged on the side portion 112 of the box body 11. To take out the mask 13, the box cover 12 is dismounted, and the mask 13 is moved out of the accommodating space 111 through the opening 1121. When the box cover 12 is dismounted, contaminants such as particles outside the box body 11 will not fall into the accommodating space 111, which effectively prevents the mask 13 or the accommodating space 111 from being contaminated, thereby ensuring the cleanliness of the mask 13.

Before the mask 13 is transferred, the side portion 112 of the box body 11 is closely attached to an outer side wall of a device body 4 of a mask transfer device, such that the opening 1121 is butted with an inlet 411 of the device body 4.

During the transfer process of the mask 13, the mask 13 is moved out of the accommodating space 111 through the opening 1121, and enters the operating space 41 of the device body 4 from the inlet 411 of the device body 4, thereby completing the transfer process of the mask 13. The box cover 12 of the mask pod box 1 is a side-opening type, which effectively prevents interference from the environment outside the box body 11 and avoids airflow disturbance, so as to further protect the mask 13 and the operating space 41. It prevent contaminants such as particles from being brought into the operating space 41 to affect the cleanliness of the mask 13, thereby effectively improving the safety of the wafer and increasing productivity.

The box cover 12 is detachably connected and installed at the side portion 112 of the box body 11 to close the opening 1121.

In an example, the projection area of the opening 1121 of the box body 11 on the side portion 112 is equal to the projection area of the accommodating space 111 on the side portion 112, so as to provide enough space to smoothly place the mask 13 or pick the mask 13. The box cover 12 may be directly mounted to the opening 1121 to close the opening 1121. The orthographic projection area of the box cover 12 mounted on the side portion 112 may be slightly larger than the orthographic projection area of the opening 1121, such that the box cover 12 can be tightly clamped into the opening 1121, thereby improving the reliability of the connection between the box cover 12 and the box body 11. The box cover 12 is dismounted when the mask 13 needs to be taken out of the accommodating space 111. The mask pod box has a simple structure and is easy to operate.

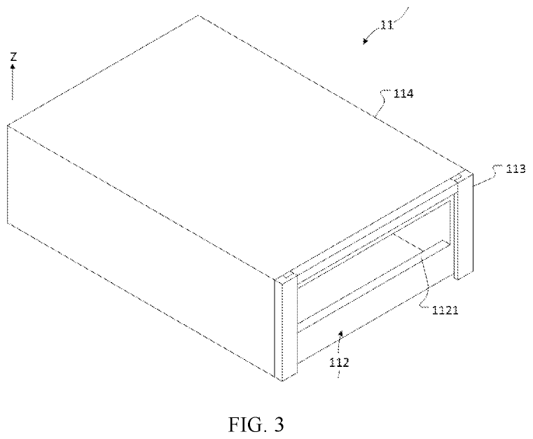

In some embodiments of the present disclosure, as shown in FIGS. 2 and 3, the mask pod box 1 includes a box body 11 and a box cover 12. The box body 11 and the box cover 12 are detachably connected. An accommodating space 111 is provided in the box body 11. An opening 1121 connecting the accommodating space 111 and the outside is arranged on a side portion 112 of the box body 11. A mask 13 is placed in the accommodating space 111 through the opening 1121. The box body 11 includes a mounting portion 113 and a box main body 114. The mounting portion 113 is fixed to the box main body 114. The mounting portion 113 may be fixed to the box main body 114 by bonding. The mounting portion 113 may also be fixed to the box main body 114 in a screwed manner. Alternatively, the mounting portion 113 may be integrated with the box main body 114 by injection molding. The mounting portion 113 protrudes from the side portion 112 to shield the opening 1121 and further prevent particles from entering the accommodating space 111.

It should be noted that the fixing of the mounting portion 113 to the box main body 114 is not limited to the above method, as long as the mounting portion 113 can be stably connected with the box main body 114. The accommodating space 111 and the opening 1121 are arranged on the box main body 114. The mounting portion 113 is fixedly connected with an outer side wall of the box main body 114 and is located on the same side of the opening 1121.

The box cover 12 is detachably connected with the box main body 114 by the mounting portion 113. The box cover 12 may be placed in the mounting portion 113 in a snap-fit manner. The box cover 12 may also be placed in the mounting portion 113 in an embedded manner. Alternatively, the box cover 12 may be placed in the mounting portion 113 in a sliding connection manner.

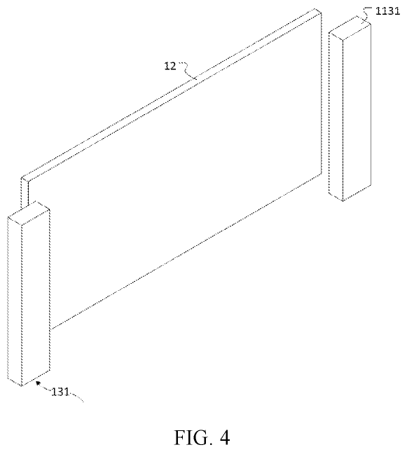

In an example, as shown in FIGS. 3 and 4, the box cover 12 may be placed in the mounting portion 113 in a snap-fit manner. The mounting portion 113 includes two protruding structures 1131, and the two protruding structures 1131 are separately arranged on two sides of the opening 1121. The protruding structure 1131 may have a rectangular shape. The protruding structures 1131 respectively extend along a thickness direction of the box main body 114 (refer to a Z-axis shown in FIG. 3), and are symmetrically arranged on left and right sides of the opening 1121. The protruding structure 1131 is fixedly connected with an edge region of the box main body 114. The box cover 12 is clamped between the two protruding structures 1131. The distance between the two protruding structures 1131 may be slightly smaller than the width of the box cover 12, such that the box cover 12 is tightly connected with the two protruding structures 1131 in a mounted state. This design can prevent the box cover 12 from detaching from the box main body 114, thereby effectively improving the reliability of the connection between the box cover 12 and the box main body 114.

It should be noted here that the above-mentioned terms related to orientations such as left and right are intended to interpret the example on the basis of those shown in the figure, rather than to limit the present application.

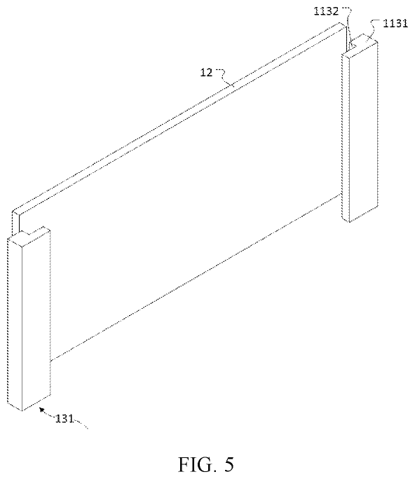

In another example, as shown in FIGS. 3 and 5, the mounting portion 113 includes two protruding structures 1131. The structure and arrangement of the protruding structures 1131 are described in detail in the above example, and will not be repeated here.

In this example, the protruding structure 1131 is further provided with an insertion groove 1132. The insertion groove 1132 penetrates the protruding structure 1131 along an extending direction of the protruding structure 1131 (refer to a Z-axis shown in FIG. 3). The insertion groove 1132 also penetrates a sidewall of the protruding structure 1131 adjacent to the opening 1121, such that an edge of the box cover 12 can be inserted in the insertion groove 1132.

With the help of an external force, the edge of the box cover 12 is inserted into the insertion groove 1132 from one end of the insertion groove 1132 to close the opening 1121. The box cover 12 is pulled out of the insertion groove 1132 along an extending direction of the insertion groove 1132 to open the opening 1121. In this way, the mounting and dismounting of the box cover 12 are realized.

The force applied to insert the box cover 12 into the insertion groove 1132 may not be controllable. If it is excessive, the box cover 12 may easily slide out of the insertion groove 1132 from the other end of the insertion groove 1132. Therefore, the mounting portion 113 further includes a limiting block 1133 arranged on the box main body 114. The limiting block 1133 is provided between the two protruding structures 1131 and located above the opening 1121. When the edge of the box cover 12 is inserted into the insertion groove 1132, by the external force, the box cover 12 is pushed from one end of the insertion groove 1132 to the other end thereof. When the box cover 12 abuts against the limiting block 1133, the limiting block 1133 prevents the box cover 12 from continuing to move, thereby preventing the box cover 12 from being pushed out of the insertion groove 1132.

It should be noted that the two ends of the limiting block 1133 may not extend to the protruding structure 1131, or may extend to the corresponding protruding structure 1131. The specific length of the limiting block 1133 is subject to requirements.

It should be noted that the above-mentioned terms related to orientations are intended to interpret the example on the basis of those shown in the figure, rather than to limit the present application.

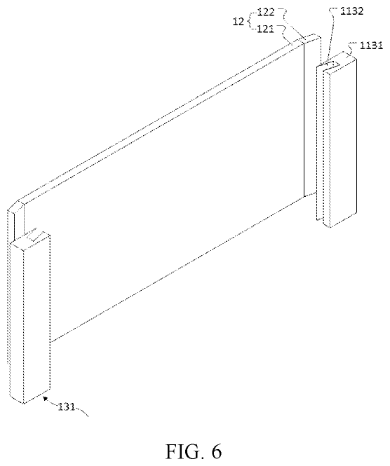

In another example, as shown in FIGS. 3 and 6, the mounting portion 113 includes a limiting block 1133 and two protruding structures 1131. The structure and arrangement of the protruding structures 1131 and the structure and arrangement of the limiting block 1133 are described in detail in the above example, and will not be repeated here.

In this example, the protruding structure 1131 is provided with an insertion groove 1132, and the cross section of the insertion groove 1132 may be quadrilateral. The quadrilateral may be a parallelogram, a rectangle, a trapezoid or a rhombus, etc.

For example, in the following description, the cross section of the insertion groove 1132 is a parallelogram.

The box cover 12 includes a cover main body 121 and an insertion body 122 matched with the insertion groove 1132. The box cover 12 is an integral structure. The insertion body 122 is formed by bending the edge of the cover main body 121 relative to the cover main body 121. The cross section of the insertion body 122 is also a parallelogram. The insertion body 122 and the insertion groove 1132 are in assembled connection. The cover main body 121 is able to slide along the insertion groove 1132 by the insertion body 122 to open or close the opening 1121.

It should be noted that when the cross section of the insertion groove 1132 is in other shape, the processing of the insertion body 122 is similar to the that described above, and will not be repeated here.

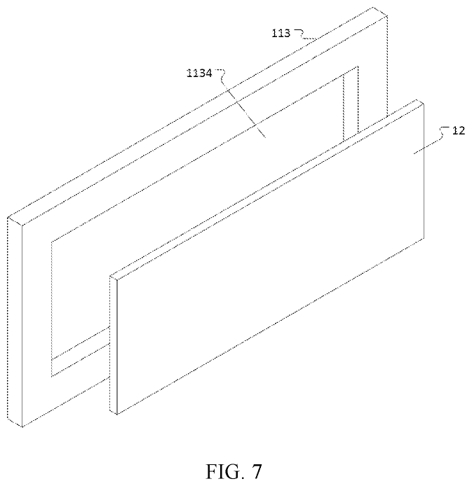

In another example, as shown in FIGS. 3 and 7, the mounting portion 113 has a frame structure. The frame structure may include four rectangular blocks. The four rectangular blocks are connected in sequence to form a hollow region 1134. When the box cover 12 is mounted to the hollow region 1134, the box cover 12 is embedded in the frame structure, so as to close the opening 1121.

The orthographic projection area of the hollow region 1134 of the frame structure on the box main body 114 is equal to the orthographic projection area of the box cover 12 on the box main body 114. In this way, the box cover 12 fits with the hollow region 1134 to improve the connection effect between the box cover 12 and the mounting portion 113 and prevent the box cover 12 from leaving the hollow region 1134.

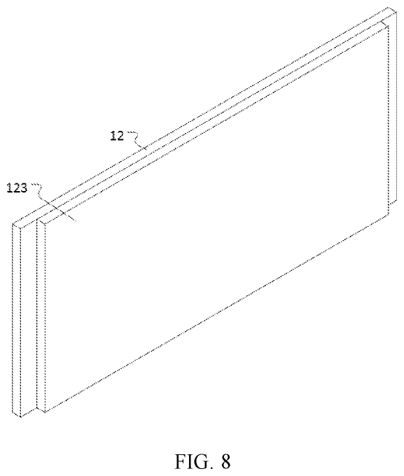

In any of the above examples, as shown in FIGS. 3 and 8, in order to ensure the overall flatness of the mask pod box 1, an outer wall of one side of the box cover 12 away from the opening 1121 is further provided with a convex platform 123. In an assembled state, a surface of the convex platform 123 is flush with that of the mounting portion 113.

In some embodiments of the present disclosure, as shown in FIG. 2, the mask pod box 1 includes a box body 11, a box cover 12 and a sealing structure 14. The sealing structure 14 is arranged on a side portion 112 of the box body 11 and located between the box body 11 and the box cover 12.

An accommodating space 111 is provided in the box body 11. The side portion 112 of the box body 11 is provided with an opening 1121 connecting the accommodating space 111 and the outside. The sealing structure 14 is arranged along a circumferential direction of the opening 1121.

In the assembled state, the sealing structure 14 can fill the gap between the box cover 12 and the box body 11 and improve the tightness of the mask pod box 1, thereby preventing particles and other contaminants from entering the accommodating space 111 through the opening 1121.

The sealing structure 14 may be a sealing ring. The sealing ring is made of an elastic rubber material, which makes the sealing ring certainly elastic. When the box cover 12 is mounted to the box body 11, the box cover 12 squeezes the sealing structure 14 such that the box cover 12 is smoothly assembled with the box body 11. After the box cover 12 is mounted, in a natural state, the sealing structure 14 has a rebound effect to fill the gap between the box cover 12 and the box body 11, thereby ensuring the sealing performance of the mask pod box 1.

In some embodiments of the present disclosure, as shown in FIGS. 2 and 9, the mask pod box 1 includes a box body 11, a box cover 12 and a plurality of supporting bodies 15.

The box body 11 is provided therein with an accommodating space 111, and an opening 1121 connecting the accommodating space 111 and the outside is arranged on a side portion 112 of the box body 11. The plurality of supporting bodies 15 are arranged at intervals on an inner bottom wall of the accommodating space 111. A mask 13 is placed on the plurality of supporting bodies 15, which raise the height of the mask 13. There is a preset distance between a lower surface of the mask 13 and the inner bottom wall of the accommodating space 111 along a thickness direction of the mask pod box 1 (refer to a Z-axis direction shown in FIG. 2). Thus, a driving arm 6 of the mask transfer device can extend from an opening 1121 to the bottom of the mask 13 and move the mask 13 out of the accommodating space 111.

In order to smoothly move the mask 13 out of the accommodating space 111, the orthographic projection area of the opening 1121 on the side portion 112 of the box body 11 is larger than the orthographic projection area of the mask 13 on the side portion 112 of the box body 11. That is, the area of the opening 1121 is larger than that of a corresponding sidewall of the mask 13. The opening 1121 is reserved with a sufficient size, so as to smoothly pick or place the mask 13 in the accommodating space 111.

The present disclosure further proposes a mask transfer device. The mask transfer device includes a driving device and a mask pod box. The driving device drives a box cover to move along a thickness direction of the mask pod box to open or close an opening. The driving device drives a box cover to move relative to a box body to realize the automation of the mask transfer device.

In some embodiments of the present disclosure, as shown in FIGS. 2, 9 and 10, a mask transfer device includes a driving device 2 and a mask pod box 1. The mask pod box 1 is connected with the driving device 2. The driving device 2 drives the box cover 12 to reciprocate along a thickness direction of the mask pod box 1 (refer to a Z-axis direction shown in FIG. 9) so as to open or close an opening 1121.

As shown in FIG. 9, the mask transfer device further includes a carrying platform 3, and the mask pod box 1 is placed on the carrying platform 3. In order to improve the reliability of the connection between the carrying platform 3 and the mask pod box 1, a clamping claw (not shown in the figure) is arranged on the carrying platform 3. The carrying platform 3 clamps the mask pod box 1 by the clamping claw, and then the carrying platform 3 transfers the mask pod box 1 to a preset position by the clamping claw.

In an example, as shown in FIG. 9, an upper surface of the box body 11 of the mask pod box 1 is provided with a grip portion 16. The carrying platform 3 clamps the grip portion 16 by the clamping claw, and restricts the movement of the mask pod box 1 by the grip portion 16, thereby improving the stability of the connection between the mask pod box 1 and the carrying platform 3.

When a force is applied to the box cover 12 of the mask pod box 1, the clamping claw on the carrying platform 3 restricts the movement of the mask pod box by the grip portion 16. Thus, the mask pod box 1 can be stably fixed at a predetermined position without misalignment or displacement, thereby ensuring the smooth transfer of the mask 13.

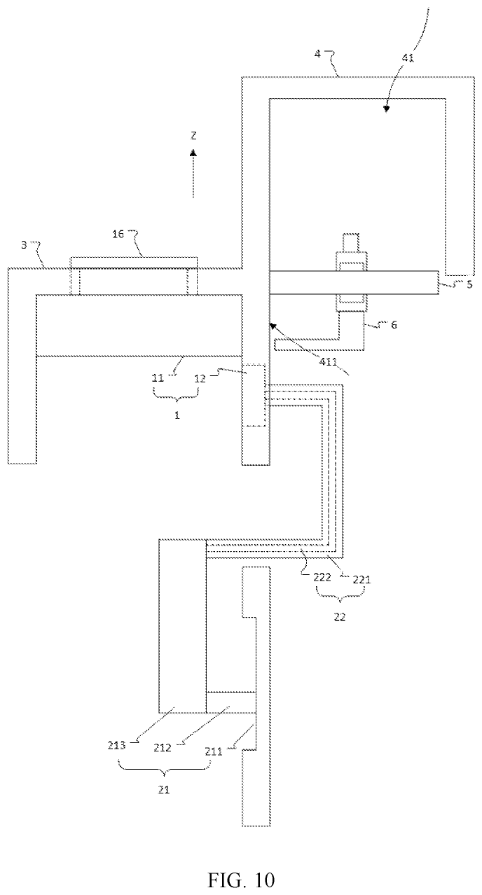

In some embodiments of the present disclosure, as shown in FIGS. 9 and 10, the mask transfer device further includes a device body 4. The device body 4 is fixedly connected with the carrying platform 3. The carrying platform 3 is used to transfer the mask pod box 1 to a preset position.

As shown in FIGS. 2 and 8, when the mounting portion 113 is a protruding structure 1131, the length of the limiting block 1133 extends to the corresponding protruding structure 1131, and the limiting block 1133 abuts against the device body 4. When the box cover 12 is dismounted to transfer the mask 13, the limiting block 1133 above can intercept contaminants such as particles on the side of the carrying platform 3.

When the mounting portion 113 has a frame structure, the frame structure abuts against the device body 4, which can also intercept contaminants such as particles on the side of the carrying platform 3 so as to further ensure the cleanliness of the mask 13.

The device body 4 is provided therein with an operating space 41, and the device body 4 is provided with an inlet 411 connecting the outside and the operating space 41. When the mask pod box 1 reaches a preset position, the inlet 411 corresponds to the opening 1121 of the mask pod box 1 such that the mask 13 can directly enter the operating space 41 through the inlet 411.

In order to ensure the cleanliness of the operating space 41, the inlet 411 is provided with a door (not shown in the figure). When the mask 13 needs to be moved into the operating space 41, the door is opened. When the movement of the mask 13 is completed, the door is closed to isolate the external environment.

In some embodiments of the present disclosure, as shown in FIGS. 9 and 10, the driving device 2 includes a moving unit 21. The moving unit 21 drives the box cover 12 to move relative to the box body 11.

The moving unit 21 includes a sliding groove 211 and a moving slider 212. The moving slider 212 is slidably connected with the sliding groove 211. The moving slider 212 is connected with an adsorption unit 22. The moving slider 212 may be detachably connected with the box cover 12. When the moving slider 212 and the box cover 12 are in an assembled state, the moving slider 212 is able to drive the box cover 12 to move relative to the box body 11.

In order to realize the automation of the mask transfer device, the moving unit 21 further includes a first driving portion 213. The first driving portion 213 drives the moving slider 212 to slide in the sliding groove 211.

In an example, the first driving portion 213 may be a driving motor, and the moving slider 212 is sleeved on a driving shaft of the driving motor. When the driving shaft of the driving motor is running, the moving slider 212 moves, and the sliding groove 211 restricts the moving direction of the moving slider 212, ensuring that the moving slider 212 moves along a preset direction. The preset direction is the same as the thickness direction of the mask pod box 1.

In another example, the first driving portion 213 may be a driving cylinder. A piston end of the driving cylinder is fixedly connected with the moving slider 212, and the driving cylinder drives the moving slider 212 to move along the sliding groove 211 by the piston end.

In some embodiments of the present disclosure, as shown in FIGS. 9 and 10, the driving device 2 further includes the adsorption unit 22. The adsorption unit 22 is respectively connected with the box cover 12 and the moving slider 212. The moving slider 212 drives the box cover 12 to move relative to the box body 11 by the adsorption unit 22.

The adsorption unit 22 may be connected with the box cover 12 in a magnetic manner. Alternatively, the adsorption unit 22 may be connected with the box cover 12 in a negative pressure adsorption manner.

In an example, one end of the adsorption unit 22 is connected with a negative pressure generating device (not shown in the figure), and the other end of the adsorption unit 22 is connected with the box cover 12.

The negative pressure generating device is configured to generate a negative pressure on a surface where the adsorption unit 22 and the box cover 12 are connected, such that the box cover 12 is adsorbed to the other end of the adsorption unit 22.

The adsorption unit 22 includes a connecting rod 221, and an air flow passage 222 is provided in the connecting rod 221. The negative pressure generating device generates a negative pressure in the air flow passage 222 such that the connecting rod 221 adsorbs the box cover 12.

As shown in FIG. 9, when the opening 1121 of the box body 11 is in a closed state and the mask 13 needs to be removed, the first driving portion 213 applies a downward traction force to the moving slider 212 to drive the moving slider 212 to slide along the sliding groove 211. A negative pressure is generated on a surface where the other end of the connecting rod 221 is connected with the box cover 12, such that the box cover 12 is adsorbed to the connecting rod 221. The moving slider 212 drives the box cover 12 to move relative to the box body 11 by the connecting rod 221 until the opening 1121 is opened to reveal the accommodating space 111.

As shown in FIG. 10, when the opening 1121 of the box body 11 is in an open state and the transfer of the mask 13 is completed, the first driving portion 213 applies an upward traction force to the moving slider 212 to drive the moving slider 212 to slide along the sliding groove 211. The moving slider 212 drives the box cover 12 to move relative to the box body 11 by the connecting rod 221 to close the opening 1121. A back pressure in the air flow passage 222 causes the connecting rod 221 to be separated from the box cover 12.

In some embodiments of the present disclosure, as shown in FIGS. 9 and 10, the mask transfer device further includes a second driving portion 5 and a driving arm 6. The second driving portion 5 is connected with the driving arm 6. The second driving portion 5 drives the driving arm 6 to move between an initial position and the accommodating space 111 to transfer the mask 13. The initial position of the driving arm 6 may be a pre-mounting position in the operating space 41.

It should be noted that the mask transfer device further includes a control unit, and the mask transfer device relies on the control unit to achieve a control function. The control unit is not limited to controlling the operation of the driving device 2 and the second driving portion 5, and the automatic function of the mask transfer device also relies on the control unit.

Those skilled in the art will easily think of other embodiments of the present disclosure after considering the specification and practicing the disclosure disclosed herein. The present application is intended to cover any variations, uses, or adaptive changes of the present disclosure. These variations, uses, or adaptive changes follow the general principles of the present disclosure and include common knowledge or conventional technical means in the technical field that are not disclosed by the present disclosure. The description and the embodiments are to be regarded as exemplary only, and the true scope and spirit of the present disclosure are pointed out by the following claims.

It should be understood that the present disclosure is not limited to the precise structure that has been described above and shown in the drawings, and various modifications and changes can be made without departing from its scope. The scope of the present disclosure is defined only by the appended claims.

### INDUSTRIAL APPLICABILITY

According to the mask pod box and the mask transfer device provided by the present disclosure, the opening of the mask pod box is arranged on the side portion of the box body. When the box cover of the mask pod box is dismounted, contaminants such as particles are intercepted and will not fall from above into the accommodating space, which ensures the cleanliness of the mask. Meanwhile, the opening is located on the side portion of the box body, corresponding to the inlet of the mask transfer device, such that the mask can directly enter the device from the side opening. This design avoids airflow disturbance and prevents particles on the carrying platform from being brought into the device.

1. A mask pod box, wherein the mask pod box comprises:
a box body, wherein an accommodating space is provided in the box body; an opening connecting the accommodating space and the outside is arranged on a side portion of the box body; a mask is placed in the accommodating space through the opening; and
a box cover, wherein the box cover is detachably connected and installed at the side portion of the box body to close the opening.

2. The mask pod box according to claim 1, wherein the box body comprises a mounting portion and a box main body; the mounting portion is fixed to the box main body; the box cover is detachably connected with the box main body by the mounting portion.

3. The mask pod box according to claim 2, wherein the mounting portion comprises two protruding structures; the two protruding structures are separately arranged on two sides of the opening; the box cover is clamped between the two protruding structures.

4. The mask pod box according to claim 3, wherein the protruding structure is provided with an insertion groove; the insertion groove penetrates the protruding structure along an extending direction of the protruding structure; an edge of the box cover is placed in the insertion groove.

5. The mask pod box according to claim 4, wherein the box cover is an integral structure; the box cover comprises a cover main body and an insertion body matched with the insertion groove;
the cover main body is able to slide along the insertion groove by the insertion body to open or close the opening.

6. The mask pod box according to claim 2, wherein the mounting portion has a frame structure; the box cover is embedded in the frame structure to close the opening.

7. The mask pod box according to claim 1, wherein the mask pod box further comprises a sealing structure arranged on the side portion of the box body and located between the box body and the box cover; the sealing structure is arranged along a circumferential direction of the opening.

8. The mask pod box according to claim 7, wherein the sealing structure is made of an elastic rubber material.

9. The mask pod box according to claim 1, wherein an orthographic projection area of the opening on the side portion of the box body is larger than the orthographic projection area of the mask on the side portion of the box body.

10. The mask pod box according to claim 1, wherein the mask pod box further comprises a plurality of supporting bodies; the plurality of supporting bodies are arranged on an inner bottom wall of the accommodating space; the mask is placed on the plurality of supporting bodies.

11. The mask pod box according to claim 1, wherein a convex platform is further arranged on an outer wall of one side of the box cover away from the opening.

12. The mask pod box according to claim 1, wherein a grip portion is arranged on an upper surface of the box body along a thickness direction of the mask pod box.

13. A mask transfer device, comprising a driving device and the mask pod box according to claim 1, wherein the driving device drives the box cover to move along the thickness direction of the mask pod box to open or close the opening.

14. The mask transfer device according to claim 13, wherein the driving device comprises a moving unit; the moving unit is able to drive the box cover to move relative to the box body.

15. The mask transfer device according to claim 14, wherein the moving unit comprises a sliding groove and a moving slider slidably connected with the sliding groove;
the moving unit further comprises a first driving portion; the first driving portion is able to drive the moving slider to slide in the sliding groove.

16. The mask transfer device according to claim 15, wherein the driving device further comprises an adsorption unit; the adsorption unit is connected with the box cover and the moving slider, respectively.

17. The mask transfer device according to claim 16, wherein one end of the adsorption unit is connected with a negative pressure generating device, and the other end of the adsorption unit is connected with the box cover;
the negative pressure generating device is configured to generate a negative pressure on a surface where the adsorption unit and the box cover are connected, so that the box cover is adsorbed to the other end of the adsorption unit.

18. The mask transfer device according to claim 17, wherein the adsorption unit comprises a connecting rod, and an air flow passage is provided in the connecting rod.

19. The mask transfer device according to claim 13, wherein the mask transfer device further comprises a second driving portion and a driving arm; the second driving portion is able to drive the driving arm to move between an initial position and the accommodating space, to transfer the mask.

20. The mask transfer device according to claim 13, wherein the mask transfer device further comprises a device body; an operating space is provided in the device body, and the device body is provided with an inlet connecting the outside and the operating space.
